(19) United States
(12) Patent Application Publication
(10) Pub. No.: US 2006/0130755 A1
(43) Pub. Date: Jun. 22, 2006

(54) Pulsed mass flow measurement system and method

(76) Inventor: William R. Clark, Hampstead, NH (US)

Correspondence Address: Toby H. Kusmer;McDERMOTT, WILL & EMERY, 28 State Street, Boston, MA, 02109, US

(21) Appl. No.: 11/015,442

(22) Filed: Dec. 17, 2004

(51) Int. Cl. C23C 16/00

(52) U.S. Cl. 118/715

(57) ABSTRACT

A system for measuring a pulsed mass flow rate of gas passing from an upstream source of gas to a downstream process chamber through an on/off type valve of the source of gas. The system includes a passageway for connecting the source of gas to the process chamber, a flow restrictor device dividing the passageway into an upstream portion and a downstream portion, a pressure transducer providing measurements of pressure within the upstream portion of the passageway, a temperature probe providing measurements of temperature within the upstream portion of the passageway, and a CPU connected to the pressure transducer and the temperature probe. The CPU is programmed to receive pressure measurements from the pressure transducer, temperature measurements from the temperature probe, and calculate a mass flow rate through the passageway using the pressure measurements and the temperature measurements.

### CROSS-REFERENCE TO RELATED APPLICATIONS

The present application is related to co-pending application Ser. No. ______, filed on _ (attorney docket number MKS-147), and co-pending application Ser. No. 10/822,358, filed on Apr. 12, 2004 (attorney docket number MKS-143), both of which are assigned to the assignee of the present application and incorporated herein by reference.

### FIELD OF THE INVENTION

The present disclosure relates generally to semiconductor manufacturing equipment and, more particularly, to systems and methods for delivering precise quantities of process gases to semiconductor processing chambers. Even more particularly, the present disclosure relates to a system and method for measuring pulsed mass flow of precursor gases into semiconductor processing chambers.

### BACKGROUND OF THE DISCLOSURE

The manufacture or fabrication of semiconductor devices often requires the careful synchronization and precisely measured delivery of as many as a dozen gases to a process chamber. Various recipes are used in the manufacturing process, and many discrete processing steps, where a semiconductor device is cleaned, polished, oxidized, masked, etched, doped, metalized, etc., can be required. The steps used, their particular sequence, and the materials involved all contribute to the making of particular devices.

As device sizes continue to shrink below 90 nm, the semiconductor roadmap suggests that atomic layer deposition, or ALD processes will be required for a variety of applications, such as the deposition of barriers for copper interconnects, the creation of tungsten nucleation layers, and the production of high coefficient dielectrics. In the ALD process, two or more precursor gases flow over a wafer surface in a process chamber maintained under vacuum. The two or more precursor gases flow in an alternating manner, or pulses, so that the gases can react with the sites or functional groups on the wafer surface. When all of the available sites are saturated from one of the precursor gases (e.g., gas A), the reaction stops and a purge gas is used to purge the excess precursor molecules from the process chamber. The process is repeated, as the next precursor gas (i.e., gas B) flows over the wafer surface. A cycle is defined as one pulse of precursor A, purge, one pulse of precursor B, and purge. This sequence is repeated until the final thickness is reached. These sequential, self-limiting surface reactions result in one monolayer of deposited film per cycle.

The pulses of precursor gases into the processing chamber is normally controlled using on/off-type valves which are simply opened for a predetermined period of time to deliver a desired amount of precursor gas into the processing chamber. Alternatively, a mass flow controller, which is a self-contained device consisting of a transducer, control valve, and control and signal-processing electronics, is used to deliver repeatable gas flow rate, as opposed to a mass or an amount of gas, in short time intervals. Typically the flow sensor is slow compared to the delivery time of the gas. In both cases, the amount of material (mass) flowing into the process chamber for each cycle is not actually measured.

What is still desired is a new and improved system and method for measuring pulsed mass flow of precursor gases into semiconductor processing chambers. Preferably, the system and method will actually measure the amount of material (mass) flowing into the process chamber in real time. In addition, the system and method will preferably provide highly repeatable and precise quantities of gaseous mass for use in semiconductor manufacturing processes, such as atomic layer deposition (ALD) processes.

### SUMMARY OF THE DISCLOSURE

The present disclosure provides a system for measuring a pulsed mass flow rate of gas passing from an upstream source of gas to a downstream process chamber through an on/off type valve of the source of gas. The system includes a passageway for connecting the source of gas to the process chamber, a flow restrictor device dividing the passageway into an upstream portion and a downstream portion, a pressure transducer providing measurements of pressure within the upstream portion of the passageway, a temperature probe providing measurements of temperature within the upstream portion of the passageway, and a CPU connected to the pressure transducer, the temperature probe and the valve. The CPU is programmed to receive pressure measurements from the pressure transducer and the temperature measurements from the temperature probe, and calculate a mass flow rate through the passageway using the pressure measurements and the temperature measurements.

According to one aspect of the present disclosure, the mass flow rate through the passageway is calculated using the following equation:
q=CAP[(M/RᵤT)·k·((2/k+1))^{k+/k-1}]^{1/2} (1)

Wherein q is the mass flow rate, P is the pressure in the upstream portion of the passageway provided by the pressure transducer, C is a discharge coefficient of the flow restrictor device, A is a cross-sectional area of aperture(s) of the flow restrictor device, M is the molecular weight of the flowing gas, Rᵤ is the universal gas constant, T is the temperature of the flowing gas, and k is the specific heat ratio of the flowing gas.

Among other aspects and advantages, the present disclosure provides a new and improved system and method for measuring pulsed mass flow of precursor gases into semiconductor processing chambers. The mass flow measurement system and method actually measures the amount of material (mass) flowing into the process chamber. In addition, the system and method provide highly repeatable and precise quantities of gaseous mass for use in semiconductor manufacturing processes, such as atomic layer deposition (ALD) processes.

Additional aspects and advantages of the present disclosure will become readily apparent to those skilled in this art from the following detailed description, wherein an exemplary embodiment of the present disclosure is shown and described, simply by way of illustration. As will be realized, the present disclosure is capable of other and different embodiments and its several details are capable of modifications in various obvious respects, all without departing from the disclosure. Accordingly, the drawings and description are to be regarded as illustrative in nature, and not as restrictive.

### BRIEF DESCRIPTION OF THE DRAWINGS

Reference is made to the attached drawings, wherein elements having the same reference characters represent like elements throughout, and wherein:

FIG. 1 is a schematic illustration of an exemplary embodiment of a pulsed mass flow measurement system constructed in accordance with the present disclosure;

FIG. 2 is a schematic illustration of another exemplary embodiment of a pulsed mass flow measurement system constructed in accordance with the present disclosure;

FIG. 3 is a schematic illustration of two of the pulsed mass flow measurement systems of FIG. 1 shown connected between exemplary embodiments of an atomic layer deposition system and two chemical selection manifolds;

FIG. 4 is a schematic illustration of two of the pulsed mass flow measurement systems of FIG. 2 shown connected between exemplary embodiments of an atomic layer deposition system and two chemical selection manifolds;

FIG. 5 is a schematic illustration of the pulsed mass flow measurement system of FIG. 1, along with two heating and pressure control units, shown connected between an atomic layer deposition system and two chemical selection manifolds;

FIG. 6 is a schematic illustration of the pulsed mass flow measurement system of FIG. 1 shown connected between an atomic layer deposition system and two chemical selection manifolds; and

FIG. 7 is a schematic illustration of an exemplary embodiment of an atomic layer deposition system constructed in accordance with the prior art.

### DETAILED DESCRIPTION OF EXEMPLARY EMBODIMENTS

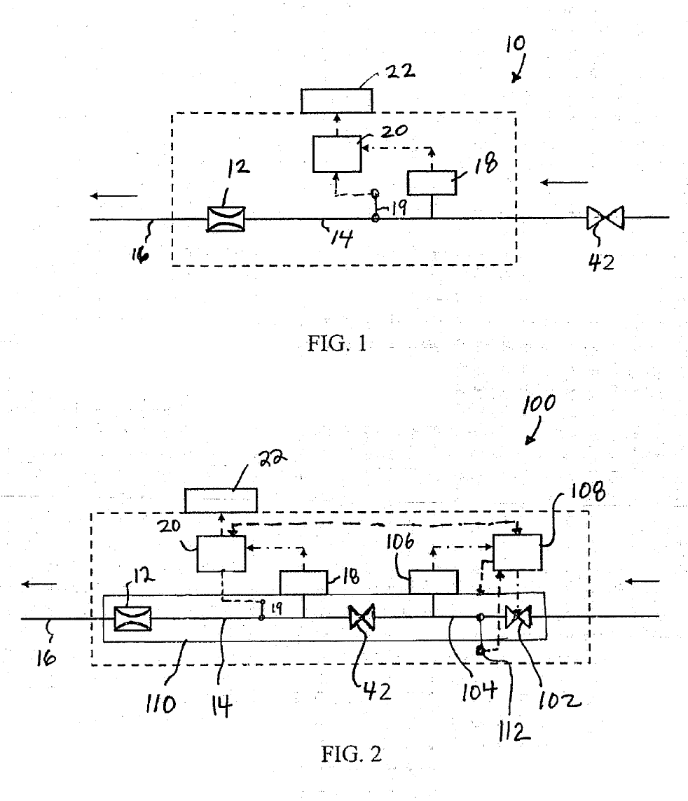

Referring to FIG. 1, the present disclosure provides an exemplary embodiment of a mass flow measurement system 10 constructed in accordance with the present invention. The system 10 is particularly intended for delivering contaminant-free, precisely metered quantities of process gases to semiconductor process chambers. The mass flow measurement system 10 actually measures the amount of material (mass) flowing into the process chamber. In addition, the system 10 provides highly repeatable and precise quantities of gaseous mass for use in semiconductor manufacturing processes, such as atomic layer deposition (ALD) processes. Prior to describing the system 10 of the present disclosure, however, an example of a semiconductor manufacturing apparatus is first described to provide background information.

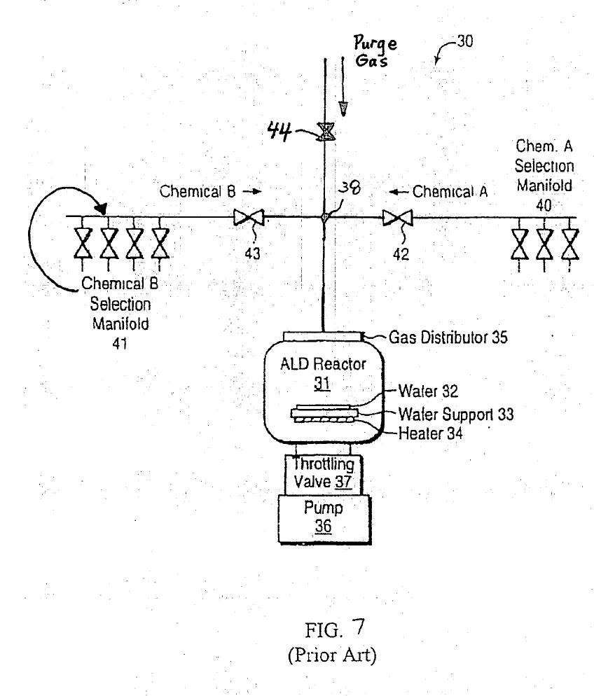

FIG. 7 is a schematic illustration of an exemplary embodiment of an atomic layer deposition system 30 constructed in accordance with the prior art. The system 30 includes a processing chamber 31 for housing a semiconductor wafer or substrate 32. Typically, the wafer 32 resides atop a support (or chuck) 33 and a heater 34 is coupled to the chuck to heat the chuck 33 and the wafer 32 for plasma deposition. The processing gases are introduced into the chamber 31 through a gas distributor 35 located at one end of the chamber 31. A vacuum pump 36 and a throttling valve 37 are located at the opposite end to draw and regulate the gas flow across the wafer surface.

A variety of chemical vapor deposition (CVD) techniques for combining gases can be utilized, including adapting techniques known in the art. Although not shown, the gases may also be made into a plasma. The system 30 also includes a multi-way connector 38 for directing the various processing gases and purge gases into the gas distributor 35 and into the processing chamber 31.

The multi-way connector 38 has two inlets for the introduction of precursor gases and a third inlet for the introduction of a purge gas. The purge gas is typically an inert gas, such as nitrogen. In the example diagram of FIG. 7, chemical A and chemical B are shown along with the purge gas. Chemistry A pertains to a first precursor gas and chemistry B pertains to a second precursor gas for performing atomic layer deposition on the semiconductor wafer 32 contained in the process chamber 31. Chemical selection manifolds 40 and 41, comprised of a number of regulated valves, provide for the selecting of chemicals that can be used as precursor gases A and B, respectively. On/off-type valves 42 and 43 respectively regulate the introduction of the precursor gases A and B into the multi-way connector 38.

Once the wafer 32 is resident within the processing chamber 31, the chamber environment is brought up to meet desired parameters. For example, the temperature of the semiconductor wafer 32 is raised in order to perform atomic layer deposition. When atomic layer deposition is to be performed, the valve 42 is opened to allow the first precursor to be introduced into the process chamber 31. After a preselected period of time, the valve 42 is closed, valve 44 is opened, and the purge gas purges any remaining reactive species from the process chamber 31. Then, after another preselected time, the valve 44 is closed to stop the purge gas, and the valve 43 is opened to introduce the second precursor into the process chamber 31. Again after another preselected time, the valve 43 is closed, the valve 44 is opened, and the purge gas purges the reactive species from the process chamber 31. The two chemicals A and B are alternately introduced into the carrier flow stream to perform the atomic layer deposition cycle to deposit a film layer on the semiconductor wafer 32.

Thus, the pulses of precursor gases into the processing chamber 31 is controlled using the on/off type valves 42 and 43 which are simply opened for a predetermined period of time to deliver a desired amount of precursor gas into the processing chamber 31. Alternatively, mass flow CPUs, which are self-contained devices consisting of a transducer, control valve, and control and signal-processing electronics, can be used in place of the on/off type valves 42 and 43 to deliver repeatable gas flow rates in timed intervals to the processing chamber 31. In both cases, the amount of material (mass) flowing into the process chamber is not actually measured. Instead flow rates are controlled to estimate the mass flow. The mass flow measurement system 10 of the present disclosure, however, actually measures the amount of material (mass) flowing into the process chamber as opposed to controlling flow rates to estimate mass flow.

Referring again to FIG. 1, the presently disclosed mass flow measurement system 10 includes a flow restrictor device 12, dividing a passageway into an upstream portion 14 and a downstream portion 16. A pressure transducer 18 is provided in the upstream portion 14 of the passageway for providing measurements of pressure within the upstream portion. The pressure transducer 18 has a relatively very fast response time of about 1 to 5 milliseconds, for example (as opposed to a typical response time of about 20 milliseconds). Examples of a suitable pressure transducer for use with the delivery system 10 of the present disclosure are Baratron® brand pressure transducers available from the assignee of the present disclosure, MKS Instruments of Andover, Mass. (http://www.mksinst.com). The system 10 also includes a temperature probe 19 provided in the upstream portion 14 of the passageway for providing measurements of temperature within the upstream portion.

The system 10 further includes a computer controller or computer processing unit (hereinafter “CPU”) 20 connected to the pressure transducer 18 and the temperature probe 19. An output device 22 is connected to the CPU 20 and provides an indication (either directly to a human operator, through an LCD for example, or indirectly through a connector for connection to a PC) of the mass delivered by the system 10.

When the pressure in the upstream portion 14 of the passageway is at least twice as great as the pressure in the downstream portion 16, the flow is said to be choked, and the flow rate is a linear function only of the pressure in the upstream portion 14 provided by the pressure transducer 18, the temperature within the upstream portion provided by the temperature probe 19, and the cross-sectional area of aperture(s) the flow restrictor device 12. In general, choked flow is typically established by maintaining the pressure in the upstream portion 14 of the passageway at least about twice that of the pressure in the downstream portion 16 of the passageway. In a choked flow regime, as the pressure of the fluid in the upstream portion 14 of the passageway increases, the density and flow rate of the fluid also increase.

However, when the pressure in the upstream portion 14 of the passageway is less than twice the pressure in the downstream portion 16, the flow is said to be unchoked and the relationship between mass flow rate and downstream fluid pressure is nonlinear. U.S. Pat. No. 5,868,159 to Loan et al., which is assigned to the assignee of the present disclosure and incorporated herein by reference, discloses the equations used to calculate flow rate based upon choked conditions and unchoked conditions.

The CPU 20 of the system 10 is programmed to calculate the flow rate as a function of the pressure in the upstream portion 14 provided by the pressure transducer 18, the temperature within the upstream portion 14 provided by the temperature probe 19, and the cross-sectional area of the flow restrictive device 12. The flow rate is calculated using the following equation:
q=CAP[(M/RᵤT)·k·((2/k+1))^{k+1/k-1}]^{1/2} (1)

Wherein q is the mass flow rate; P is the pressure in the upstream portion 14 of the passageway; C is the discharge coefficient of the flow restrictor device 12; A is the cross-sectional area of aperture(s) of the flow restrictor device 12; M is the molecular weight of the flowing gas(es); Rᵤ is the universal gas constant; T is the temperature of the flowing gas(es); and k is the specific heat ratio of the flowing gas(es). The temperature of the flowing gas(es) is provided by the temperature probe 19 to the CPU 20.

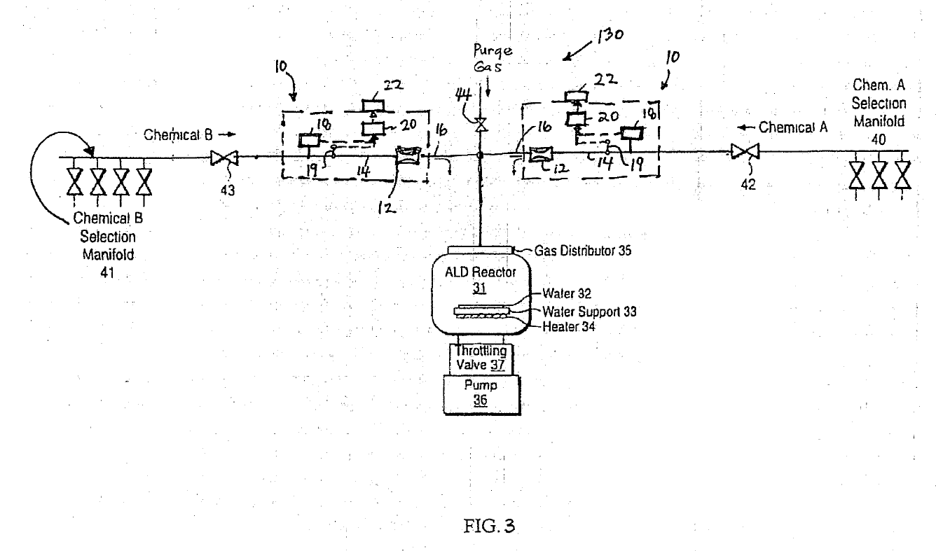

In the exemplary embodiment shown in FIG. 3, an atomic layer deposition system 130 including two of the mass flow measurement systems 10 of FIG. 1 is provided. The atomic layer deposition system 130 is similar to the prior art atomic layer deposition system 30 of FIG. 7, such that similar elements share the same reference numerals. The atomic layer deposition system 130 of FIG. 3, however, includes two of the mass flow measurement systems 10 of FIG. 1 for respectively measuring the flow rate of the precursor gases A and B into the multi-way connector 38. As shown in both FIGS. 1 and 3, the mass flow measurement systems 10 are positioned after the on/off type valves 42, 43 and before the multi-way connector 38 so that the mass flow measurement systems 10 actually measure the amount of material (mass) flowing into the atomic layer deposition system 130.

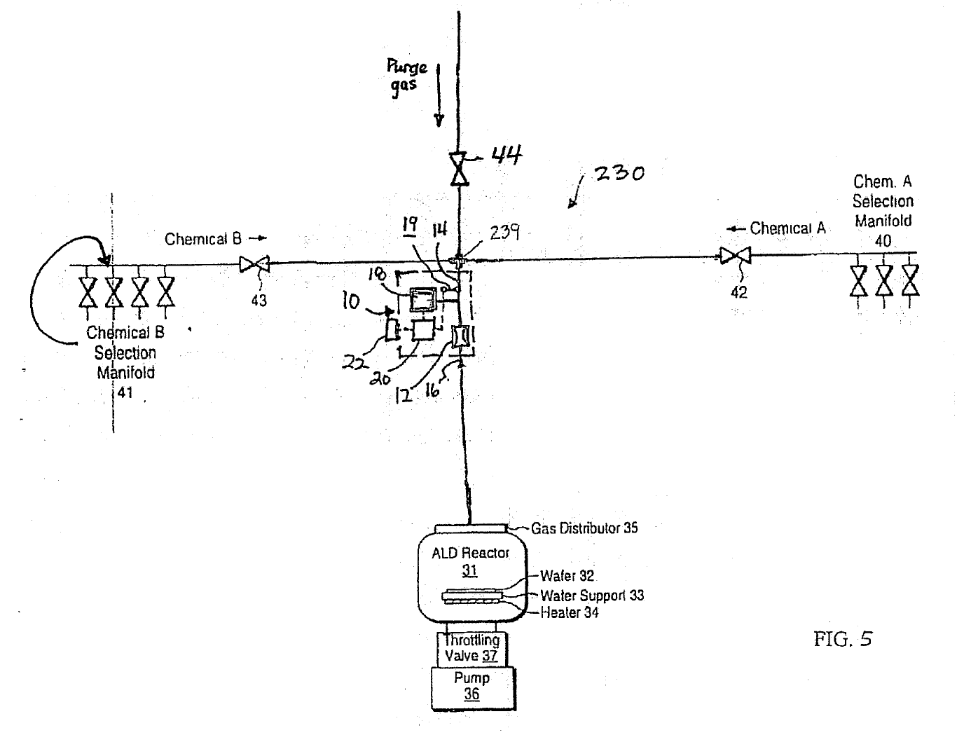

In the exemplary embodiment shown in FIG. 5, an atomic layer deposition system 230 including only one of the mass flow measurement system 10 of FIG. 1 is provided. The atomic layer deposition system 230 is similar to the prior art atomic layer deposition system 130 of FIG. 3, such that similar elements share the same reference numerals. The atomic layer deposition system 230 of FIG. 5, however, includes only one of the mass flow measurement system 10 of FIG. 1 for measuring the flow rate of both of the precursor gases A and B, and the purge gas. The mass flow measurement system 10 is positioned after a four-way connector 239, for example, connecting both of the on/off type valves 42, 43 and the purge gas to the reactor 31, so that the mass flow measurement system 10 actually measures the amount of material (mass) flowing into the atomic layer deposition system 130 from both selection manifolds 40, 41, and the purge gas.

Referring now to FIG. 2, another exemplary embodiment of a pulsed mass flow measurement system 100 constructed in accordance with the present disclosure is shown. The systems 100 is similar to the system 10 of FIG. 1, such that similar elements share the same reference numerals. The system 100 of FIG. 2, therefore, includes a fixed orifice, or flow restrictive device 12, dividing the passageway into an upstream portion 14, extending from the on/off-type valve 42 to the flow restrictor 12, and a downstream portion 16 extending from the flow restrictor 12. A pressure transducer 18 is provided in the upstream portion 14 for providing measurements of pressure within the upstream portion, a CPU 20 is connected to the pressure transducer 18, the temperature probe 19, and an output device 22 is connected to the CPU 20.

The system 100 of FIG. 2, however, further includes elements for controlling the pressure and the temperature of the vapor source, such that the performance of the pulsed mass flow measurement system 100 is repeatable and consistent. The pressure control elements are positioned upstream of the on/off-type valve 42 and include a proportional-type valve 102 positioned upstream of the on/off-type valve 42 such that the passageway is further divided into a second upstream portion 104, extending from the proportional-type valve 102 to the on/off-type valve 42. A second pressure transducer 106 is provided in the second upstream portion 104 for providing measurements of pressure within the second upstream portion, and a second CPU 108 is connected to the second pressure transducer 106 and the proportional-type valve 102. The second CPU 108 is programmed to receive pressure measurements from the second pressure transducer 106 and control the proportional-type valve 102 such that the pressure within the second upstream portion 104 remains at a predetermined level. The predetermined level of pressure can be provided by the first CPU 20 to the second CPU 108 (alternatively, the first CPU 20 can be connected directly to the second pressure transducer 106 and the proportional-type valve 102 and programmed to maintain the pressure within the second upstream portion 104 at the predetermined level).

The system 100 of FIG. 2 also includes temperature control elements for controlling the temperature of the vapor source. The elements include an insulator/heater assembly 110 extending from the proportional-type valve 102 to the flow restrictor 12 and a temperature probe 112 providing temperature measurements of the second upstream portion 104. The second CPU 108 is programmed to receive temperature measurements from the temperature probe 112 and control the insulator/heater assembly 110 such that the temperature within the second upstream portion 104 remains at a predetermined level. The predetermined level of temperature can be provided by the first CPU 20 to the second CPU 108 (alternatively, the first CPU 20 can be connected directly to the temperature probe 112 and the insulator/heater assembly 110 and programmed to maintain the temperature within the second upstream portion 104 at the predetermined level).

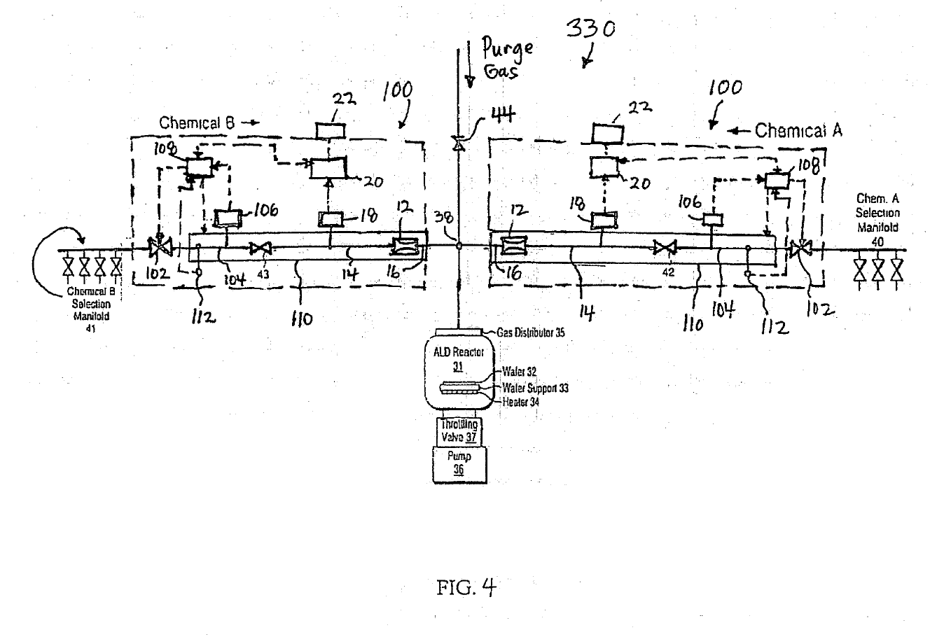

As shown in FIG. 4, an atomic layer deposition system 330 including two of the mass flow measurement systems 100 of FIG. 2 is provided. The atomic layer deposition system 330 is similar to the prior art atomic layer deposition system 30 of FIG. 7, such that similar elements share the same reference numerals. The atomic layer deposition system 330 of FIG. 4, however, includes two of the mass flow measurement systems 100 of FIG. 2 for respectively measuring the flow rate of the precursor gases A and B into the multi-way connector 38. As shown in both FIGS. 2 and 4, the mass flow measurement systems 100 are positioned before the multi-way connector 38 so that the mass flow measurement systems 100 actually measure the amount of material (mass) flowing into the atomic layer deposition system 130.

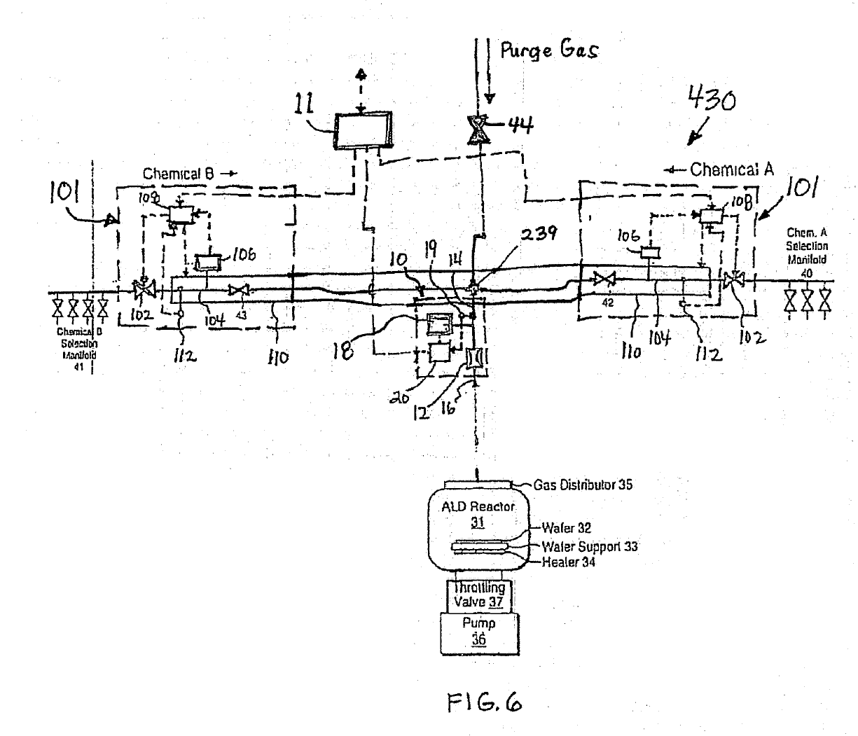

FIG. 6 shows another exemplary embodiment of an atomic layer deposition system 430 including the mass flow measurement system 10 of FIG. 1 and components of the mass flow measurement system 100 of FIG. 2. The atomic layer deposition system 430 is similar to the atomic layer deposition system 230 of FIG. 5, such that similar elements share the same reference numerals. The atomic layer deposition system 430 of FIG. 6, however, further includes two pressure and temperature control units 101 for controlling the pressure and the temperature of the vapor sources A and B. The pressure and temperature control units 101 include the pressure and temperature components from the flow measurement system 100 of FIG. 2.

The pressure and temperature control units 101 both include a proportional-type valve 102 positioned upstream of the on/off-type valves 42, 43 such that the passageway is further divided into an upstream portion 104, extending from the proportional-type valve 102 to the on/off-type valves 42, 43. A pressure transducer 106 is provided in the upstream portion 104 for providing measurements of pressure within the second upstream portion, and a CPU 108 is connected to the pressure transducer 106 and the proportional-type valve 102. The CPU 108 is programmed to receive pressure measurements from the pressure transducer 106 and control the proportional-type valve 102 such that the pressure within the second upstream portion 104 remains at a predetermined level. The predetermined level of pressure can be provided by a master CPU 11 to the CPU 108 (alternatively, the master CPU 11 can be connected directly to the pressure transducer 106 and the proportional-type valve 102 and programmed to maintain the pressure within the upstream portion 104 at the predetermined level). The master CPU 11 is also connected to the CPU 20 of the flow measurement system 10 (alternatively, the master CPU 11 can be connected directly to the components of the flow measurement system 10).

The pressure and temperature control units 101 also include a insulator/heater assembly 110 extending from the proportional-type valve 102 to the on/off-type valves 42, 43 and a temperature probe 112 providing temperature measurements of the upstream portion 104. The CPU 108 is programmed to receive temperature measurements from the temperature probe 112 and control the insulator/heater assembly 110 such that the temperature within the upstream portion 104 remains at a predetermined level. The predetermined level of temperature can be provided by the master CPU 11 to the CPU 108 (alternatively, the master CPU 11 can be connected directly to the temperature probe 112 and the insulator/heater assembly 110 and programmed to maintain the temperature within the upstream portion 104 at the predetermined level).

Among other aspects and advantages, the present disclosure provides a new and improved system for measuring pulsed mass flow of precursor gases into semiconductor processing chambers. The mass flow measurement system actually measures the amount of material (mass) flowing into the process chamber. In addition, the system provides highly repeatable and precise quantities of gaseous mass for use in semiconductor manufacturing processes, such as atomic layer deposition (ALD) processes.

The exemplary embodiments described in this specification have been presented by way of illustration rather than limitation, and various modifications, combinations and substitutions may be effected by those skilled in the art without departure either in spirit or scope from this disclosure in its broader aspects and as set forth in the appended claims.

What is claimed is:

1. A system for measuring a pulsed mass flow rate of gas passing from an upstream source of gas to a downstream process chamber through an on/off type valve of the source of gas, comprising:
a passageway for connecting the source of gas to the process chamber;
a flow restrictor device dividing the passageway into an upstream portion and a downstream portion;
a pressure transducer providing measurements of pressure within the upstream portion of the passageway;
a temperature probe providing measurements of temperature within the upstream portion of the passageway;
a computer processing unit (CPU) connected to the pressure transducer, the temperature probe and programmed to, receive pressure measurements from the pressure transducer,
receive temperature measurements from the temperature probe, and
calculate a mass flow rate through the passageway using the pressure measurements and the temperature measurements.

2. A system according to claim 1, wherein the mass flow rate through the passageway is calculated using the following equation:
q=CAP[(M/RᵤT)·k·((2/k+1))^{k+1/k-1}]^{1/2} (1)
wherein q is the mass flow rate, P is the pressure in the upstream portion of the passageway provided by the pressure transducer, C is a discharge coefficient of the flow restrictor device, A is a cross-sectional area of aperture(s) of the flow restrictor device, M is the molecular weight of the flowing gas, Rᵤ is the universal gas constant, T is the temperature in the upstream portion of the passageway provided by the temperature probe, and k is the specific heat ratio of the flowing gas.

3. A system according to claim 1, further comprising an output device connected to the CPU, and wherein the CPU is programmed to provide the calculated mass flow rate to the output device.

4. A system according to claim 1, further comprising a process chamber connected to the downstream portion of the passageway.

5. A system according to claim 1, wherein the pressure transducer has a response time of about 1 to 5 milliseconds.

6. A system according to claim 1, further comprising thermal insulation covering the passageway.

7. A system according to claim 6, further comprising a heating unit adjacent the passageway and connected to the CPU, and wherein the CPU is programmed to receive the measurements of the temperature of the passageway from the temperature probe and operate the heating unit until the temperature measurements of the passageway are substantially equal to a desired temperature of the passageway.

8. A system according to claim 1, further comprising:
a proportional-type valve for being positioned in the passageway upstream of the on/off type valve of the source of gas and connected to the CPU; and
a pressure transducer for providing measurements of pressure within the passageway upstream of the on/off type valve of the source of gas;
wherein the CPU is programmed to receive the measurements of the pressure within the passageway upstream of the on/off type valve of the source of gas and operate the proportional-type valve until the pressure within the passageway upstream of the on/off type valve of the source of gas is substantially equal to a desired pressure of the source of gas.

9. A system according to claim 1, further comprising a multi-way connector in the upstream portion of the passageway for connecting two sources of gas to the system.

10. A method for measuring a pulsed mass flow rate of gas passing from an upstream source of gas to a downstream process chamber through an on/off type valve of the source of gas, comprising:
connecting the source of gas to the process chamber through a passageway;
dividing the passageway into an upstream portion and a downstream portion using a flow restrictor device;
measuring pressure within the upstream portion of the passageway;
measuring temperature within the upstream portion of the passageway; and
calculate a mass flow rate through the passageway using the pressure measurements and the temperature measurements in the upstream portion of the passageway.

11. A method according to claim 10, wherein the mass flow rate through the passageway is calculated using the following equation:
q=CAP[(M/RᵤT)·k·((2/k+1))^{k+1/k-1}]^{1/2} (1)
wherein q is the mass flow rate, P is the pressure in the upstream portion of the passageway provided by the pressure transducer, C is a discharge coefficient of the flow restrictor device, A is a cross-sectional area of aperture(s) of the flow restrictor device, M is the molecular weight of the flowing gas, Rᵤ is the universal gas constant, T is the temperature of the flowing gas, and k is the specific heat ratio of the flowing gas.

12. A method according to claim 10, further comprising providing the calculated mass flow rate to an output device.

13. A method according to claim 10, further comprising providing thermal insulation around the passageway.

14. A method according to claim 13, further comprising heating the passageway until the temperature measurements of the passageway are substantially equal to a desired temperature of the passageway.

15. A method according to claim 10, further comprising:
controlling flow in the passageway upstream of the on/off type valve of the source of gas using a proportional-type valve;
measuring pressure within the passageway upstream of the on/off type valve of the source of gas; and
operate the proportional-type valve until the pressure within the passageway upstream of the on/off type valve of the source of gas is substantially equal to a desired pressure of the source of gas.

16. A system for measuring a pulsed mass flow rate of gas passing from at least two upstream sources of gas to a downstream process chamber, comprising:
a passageway for connecting the sources of gas to the process chamber;
a temperature probe providing measurements of temperature of the passageway;
a flow restrictor device dividing the passageway into an upstream portion and a downstream portion;
a pressure transducer providing measurements of pressure within the upstream portion of the passageway; and
a computer processing unit (CPU) connected to the pressure transducer and the temperature probe and programmed to receive pressure measurements from the pressure transducer, receive temperature measurements from the temperature probe, and calculate a mass flow rate through the passageway using the pressure measurements and the temperature measurements.

17. A system according to claim 16, wherein the mass flow rate through the passageway is calculated using the following equation:
q=CAP[(M/RᵤT)·k·((2/k+1))^{k+1/k-1}]^{1/2} (1)
wherein q is the mass flow rate, P is the pressure in the upstream portion of the passageway provided by the pressure transducer, C is a discharge coefficient of the flow restrictor device, A is a cross-sectional area of aperture(s) of the flow restrictor device, M is the molecular weight of the flowing gas, Rᵤ is the universal gas constant, T is the temperature of the passageway provide by the temperature probe, and k is the specific heat ratio of the flowing gas.

18. A system according to claim 16, further comprising an output device connected to the CPU, and wherein the CPU is programmed to provide the calculated mass flow rate to the output device.

19. A system according to claim 16, further comprising a process chamber connected to the downstream portion of the passageway.

20. A system according to claim 16, wherein the pressure transducer has a response time of about 1 to 5 milliseconds.

21. A system according to claim 16, further comprising on/off-type valves positioned between each of the upstream sources of gas and the system and pressure control elements for controlling pressure between the on/off-type valves and the upstream sources of gas.

22. A system according to claim 16, further comprising on/off-type valves positioned between each of the upstream sources of gas and the system and temperature control elements for controlling temperature between the on/off-type valves and the upstream sources of gas.
